(19) United States
(12) Patent Application Publication
(10) Pub. No.: US 2025/0031578 A1
(43) Pub. Date: Jan. 23, 2025

(54) PIEZOELECTRIC DEVICES TO BREAK LAMINATED GLASS ASSEMBLIES ON DEMAND

(71) Applicant: GM GLOBAL TECHNOLOGY OPERATIONS LLC, DETROIT, MI (US)

(72) Inventors: David T. Renke, Macomb, MI (US); Michael D. Richardson, Lake Orion, MI (US); Gerard Parij, Warren, MI (US); James C. O'Kane, Shelby Twp, MI (US)

(21) Appl. No.: 18/354,772

(22) Filed: Jul. 19, 2023

(51) Int. Cl. H10N 30/20; B60R 21/013; B60R 21/02; H10N 30/072; H10N 30/80

(52) U.S. Cl. CPC H10N 30/202; B60R 21/013; B60R 21/02; H10N 30/072; H10N 30/802; B60R 2021/01013; B60R 2021/01286

(57) ABSTRACT

Aspects of the disclosure include using piezoelectric devices to break laminated glass assemblies on demand (e.g., a windshield of a vehicle). An exemplary vehicle includes a laminated glass panel having an outer glass layer, an inner glass layer, and a bonding layer between the outer glass layer and the inner glass layer. The vehicle further includes a piezoelectric device including an actuator and a displaceable element coupled to the actuator. The actuator is made of a piezoelectric material that, responsive to receiving an activation voltage, induces a mechanical displacement in the displaceable element against at least one of the outer glass layer and the inner glass layer. The vehicle includes a controller electrically coupled to the actuator. The controller is configured to deliver the activation voltage to the actuator.

### INTRODUCTION

The subject disclosure relates to vehicle safety and laminated glass assemblies, and particularly to the use of piezoelectric devices to break laminated glass assemblies on demand.

Vehicle safety generally refers to the measures and features designed to minimize the risk of injury and harm to vehicle occupants (drivers and passengers), pedestrians, and other road users in the event of an automobile accident. Vehicle safety broadly encompasses various components such as crashworthiness, occupant protection, active and passive safety systems, and pedestrian safety. Regulatory bodies and vehicle manufacturers have implemented specific standards to ensure that regulated vehicles meet stringent safety requirements. These safety standards encompass various aspects of vehicle design, construction, and performance, and are continually updated and revised to address emerging safety concerns and advancements in technology.

### SUMMARY

In one exemplary embodiment a vehicle includes a laminated glass panel having an outer glass layer, an inner glass layer, and a bonding layer between the outer glass layer and the inner glass layer. The vehicle further includes a piezoelectric device including an actuator and a displaceable element coupled to the actuator. The actuator is made of a piezoelectric material that, responsive to receiving an activation voltage, induces a mechanical displacement in the displaceable element against at least one of the outer glass layer and the inner glass layer. The vehicle includes a controller electrically coupled to the actuator. The controller is configured to deliver the activation voltage to the actuator.

In addition to one or more of the features described herein, in some embodiments, the piezoelectric device is embedded within the bonding layer of the laminated glass panel. In some embodiments, the piezoelectric device is positioned against a surface of at least one of the outer glass layer and the inner glass layer of the laminated glass panel.

In some embodiments, the vehicle further includes an external system electrically coupled to the controller. In some embodiments, the external system is configured to predict an upcoming impact of the vehicle and, responsive to predicting the upcoming impact, direct the controller to deliver the activation voltage to the actuator.

In some embodiments, the external system includes one or more on-board vehicle sensors configured to detect the upcoming impact. In some embodiments, the one or more on-board vehicle sensors include at least one of a camera, a Light Detection and Ranging (LIDAR) system, a radar sensor, an ultrasonic sensor, an Inertial Measurement Unit (IMU), an accelerometer, a decelerometer, a gyroscope, and a dedicated crash sensor.

In some embodiments, the piezoelectric material includes at least one of lead zirconate titanate (PZT), potassium sodium niobate (KNN), bismuth sodium titanate (BNT), polyvinylidene fluoride (PVDF), poly-L-lactic Acid (PLLA), lead magnesium niobate-lead titanate (PMN-PT), and lithium niobate (LiNbO₃).

In some embodiments, the vehicle further includes a plurality of piezoelectric devices embedded within or positioned beside the laminated glass panel. In some embodiments, the controller is configured to selectively deliver the activation voltage to a subset of the plurality of piezoelectric devices.

In another exemplary embodiment a laminated glass panel can include an outer glass layer, an inner glass layer, and a bonding layer between the outer glass layer and the inner glass layer. A piezoelectric device including an actuator and a displaceable element is coupled to the actuator. The actuator includes a piezoelectric material that, responsive to receiving an activation voltage, induces a mechanical displacement in the displaceable element against at least one of the outer glass layer and the inner glass layer.

In some embodiments, a controller is electrically coupled to the actuator. In some embodiments, the controller is configured to deliver the activation voltage to the actuator.

In yet another exemplary embodiment a method for breaking laminated glass assemblies on demand can include providing a piezoelectric system. The piezoelectric system can include a laminated glass panel having an outer glass layer, an inner glass layer, and a bonding layer between the outer glass layer and the inner glass layer. A piezoelectric device including an actuator and a displaceable element is coupled to the actuator. The actuator includes a piezoelectric material that, responsive to receiving an activation voltage, induces a mechanical displacement in the displaceable element against at least one of the outer glass layer and the inner glass layer. The piezoelectric system includes a controller electrically coupled to the actuator. The controller is configured to deliver the activation voltage to the actuator. The method further includes detecting an upcoming impact, and responsive to detecting the upcoming impact, causing the controller to deliver the activation voltage to the actuator, thereby displacing the displaceable element into at least one of the outer glass layer and the inner glass layer.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2 is a cross-sectional view of a region of a laminated glass panel shown in FIG. 1 in accordance with one or more embodiments;

FIG. 3 illustrates an alternative configuration of the laminated glass panel shown in FIG. 2 in accordance with one or more embodiments;

FIG. 4 illustrates yet another alternative configuration of the laminated glass panel shown in FIG. 2 in accordance with one or more embodiments;

FIG. 5 illustrates a process for using a piezoelectric device to break a laminated glass assembly on demand in accordance with one or more embodiments;

FIG. 6. is a computer system according to one or more embodiments; and

FIG. 7 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

Vehicle safety tests involve various component-level and vehicle-level evaluations, such as crash tests, mechanical tests, durability tests, and compliance with specific performance criteria. Component-level tests focus on evaluating individual safety components or systems of components within a vehicle. These types of tests assess the performance and reliability of components such as seat belts, airbags, braking systems, and headlights. Vehicle-level tests, in contrast, evaluate the overall safety performance of the entire vehicle. These tests simulate real-world crash scenarios to assess structural integrity, occupant protection, and crash avoidance capabilities of the vehicle. Vehicle-level tests typically involve frontal, side, and rear impact tests.

One example of a vehicle-level test is the windshield impact test, although the glass panel which makes up a windshield (and other glass surfaces in a vehicle) can also be separately tested in respective component-level tests. The windshield, located at the front of the vehicle, serves several critical functions. For example, the windshield provides structural support to a vehicle's roof, maintains the integrity of the passenger compartment, and acts as a barrier between occupants and external elements. Therefore, a windshield should possess high strength and durability to withstand various forces and impacts.

Windshield impact tests specifically assess the performance and integrity of the windshield under different impact scenarios. These tests aim to ensure that the vehicle windshield provides adequate protection to vehicle occupants and pedestrians. One measure of windshield safety assessed using windshield impact tests is pedestrian safety, especially in view of the windshield breaking due to an impact. Pedestrian safety is an important aspect of vehicle safety. Regarding windshields specifically, the primary concern is to prevent windshields from shattering on impact into large, sharp fragments.

Vehicle safety tests related to pedestrian impacts and windshields also include, in addition to (or as part of) windshield impact tests, the headform impact test, upper legform impact test, and whole vehicle pedestrian impact test. A headform impact test uses an instrumented headform, representing a pedestrian's head, to strike different areas of a windshield. The goal of such a test is to assess the risk of head injury based on the impact energy transmitted through the windshield on impact. The windshield should be designed to absorb and distribute the impact energy to minimize injury. The upper legform impact test uses a legform impactor to simulate a pedestrian's upper leg striking the windshield. This test evaluates the risk of leg injuries in the event of an impact. Whole vehicle pedestrian impact tests involve the use of pedestrian dummies to simulate various impact scenarios, including collisions with the vehicle's windshield. The objective of these tests is to assess the overall pedestrian protection provided by the vehicle, including the windshield's performance in reducing the severity of injuries.

One approach used to improve occupant and pedestrian safety is to replace standard glass windshields with windshields made from laminated glass. Laminated glass consists of two (or more) layers of glass with a plastic interlayer sandwiched in between. A laminated construction helps to hold the glass together upon impact, reducing the risk of large fragments breaking off. Almost all modern vehicles have incorporated laminated glass windshields for this reason.

This disclosure introduces a way to use piezoelectric devices to break laminated glass assemblies on demand. Rather than allowing laminated glass assemblies (e.g., a windshield) to break on impact, aspects of the present disclosure describe a system and method whereby a laminated glass assembly is broken, pre-fractured, and/or otherwise damaged prior to an impact. In some embodiments, an upcoming impact is detected using on-board vehicle sensors, such as cameras and Light Detection and Ranging (LIDAR) systems, and the laminated glass assembly is broken responsive to detecting the upcoming impact. The laminated glass assembly can be broken by actuating the piezoelectric devices to strike a surface(s) of the laminated glass assembly. In some embodiments, piezoelectric devices are embedded within or integrated on a surface of the laminated glass assemblies of a vehicle (e.g., on or within the front windshield). In some embodiments, a control system actuates the piezoelectric devices upon receiving a control signal. The control signal can be transmitted responsive to detecting an impending impact.

Laminated glass assemblies having integrated and/or embedded piezoelectric devices configured to break the glass on demand offer several technical advantages over prior laminated glass assemblies and vehicle safety systems. Breaking a laminated glass assembly prior to impact can substantially improve safety metrics as the glass can be damaged, broken, and/or otherwise weakened prior to impact. Moreover, the integrated and/or embedded piezoelectric devices can be strategically positioned in or around a laminated glass assembly to fine-tune the breaking parameters post-impact detection. This technique can be used, for example, to weaken a portion of a windshield directly opposite an impact while leaving remaining portions of the windshield, such as those in front of a driver, intact. In this manner, laminated glass assemblies having integrated and/or embedded piezoelectric devices can increase vehicle safety for both occupants and pedestrians.

Notably, laminated glass assemblies described herein mitigate or remove entirely various aspects of uncertainty resulting from a windshield or other glass panel breaking upon impact. In particular, the laminated glass assemblies described herein can be configured to break predictably upon impact-without regard to a range of variables including windshield thickness, glass composition, geometry, impact location, the angle of impact, as well as the variables associated with the impact object, such as its size, shape, and weight. In this manner, potential impacts become well-defined scenarios with respect to windshield breakage.

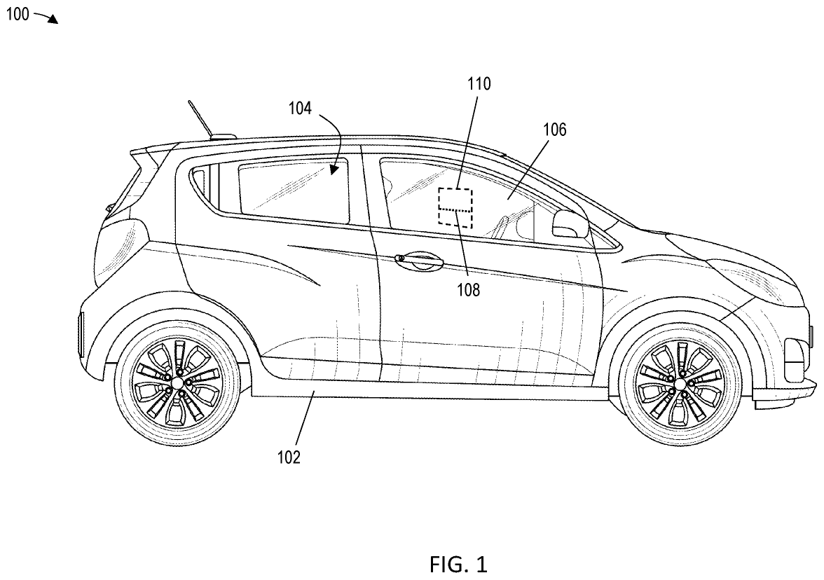

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Body 102 also includes a number of glass or glass laminate assemblies, such as, for example a laminated glass panel 106. The particular laminated glass panel 106 (here, the front passenger side window) is emphasized only for ease of illustration and discussion. It should be understood that any aspect of the present disclosure can be applied to any of the glass and glass laminate assemblies in the vehicle 100, including, for example, the front windshield, any of the driver and passenger doors (front and rear), the rear glass panel, a sunroof/moonroof, etc. In short, the location, size, arrangement, etc., of the laminated glass panel 106 is not meant to be particularly limited, and all such configurations are within the contemplated scope of this disclosure.

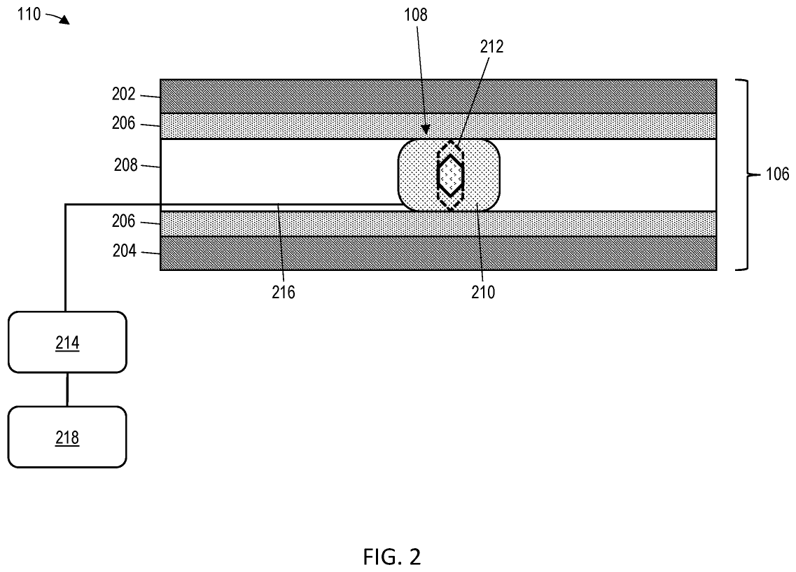

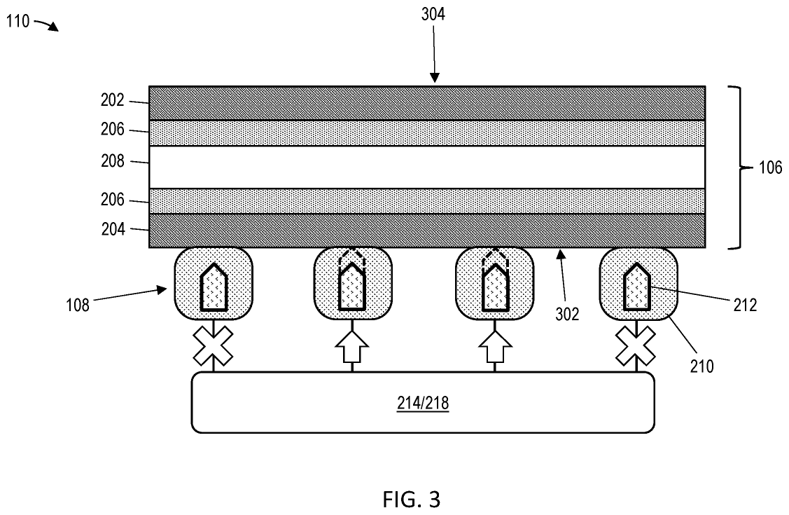

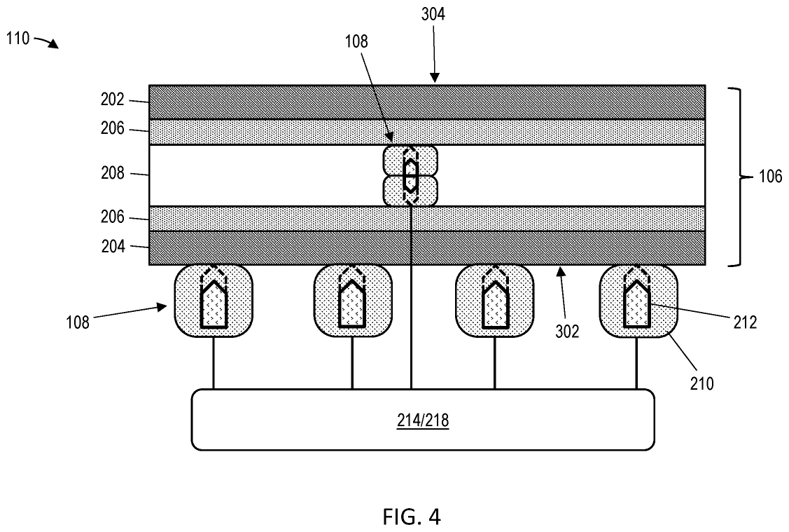

As will be detailed herein, the laminated glass panel 106 includes one or more piezoelectric devices 108 positioned to break the laminated glass panel 106 upon actuation and/or activation. In some embodiments, one or more of the piezoelectric devices 108 are embedded between one or more layers of the laminated glass panel 106 (refer to the region 110 and FIG. 2). In some embodiments, one or more of the piezoelectric devices 108 are integrated onto a surface (e.g., an inside surface, an outside surface, or both) of the laminated glass panel 106 (refer to FIG. 3). In some embodiments, one or more of the piezoelectric devices 108 are embedded between one or more layers of the laminated glass panel 106 and one or more of the piezoelectric devices 108 are integrated onto a surface of the laminated glass panel 106 (refer to FIG. 4).

The region 110 depicts an example arrangement of the one or more piezoelectric devices 108 for ease of discussion only, and it should be understood that the one or more piezoelectric devices 108 can be arranged, positioned, and/or otherwise configured anywhere within and/or on the laminated glass panel 106 as desired. All such configurations are within the contemplated scope of this disclosure. For example, in some embodiments, some or all of the piezoelectric devices 108 can be placed in the so-called blackout areas of the laminated glass panel 106 which are already obscured from view (typically located along the peripheral of a panel). In this manner, the piezoelectric devices 108 can be wholly or partially removed from a viewable area of the laminated glass panel 106 (e.g., a front windshield of the vehicle 100).

FIG. 2 illustrates a cross-sectional view of the region 110 of the laminated glass panel 106 shown in FIG. 1 after lamination in accordance with one or more embodiments. As shown in FIG. 2, the laminated glass panel 106 includes a piezoelectric device 108 laminated between an outer glass layer 202 (also referred to as outer glass ply) and inner glass layer 204 (also referred to as an inner glass ply). In some embodiments, the outer glass layer 202 includes two or more laminated glass layers. Similarly, in some embodiments, the inner glass layer 204 includes two or more laminated glass layers.

In some embodiments, the laminated glass panel 106 includes one or more inner reinforcing layers 206. In some embodiments, the laminated glass panel 106 includes a bonding layer 208. In some embodiments, the piezoelectric device 108 is laminated between the outer glass layer 202 and the inner glass layer 204 within the bonding layer 208 (as shown). In some embodiments, the one or more inner reinforcing layers 206 are positioned between the glass layers (e.g., the outer glass layer 202 and the inner glass layer 204) and the bonding layer 208.

The material composition(s) of the outer glass layer 202, the inner glass layer 204, the inner reinforcing layers 206, and the bonding layer 208 (collectively, the laminate layers) are not meant to be particularly limited and will vary depend on the needs of the respective application (e.g., desired structural, thermal, and optical properties, etc. of the laminated glass panel 106). In some embodiments, for example, the inner reinforcing layers 206 can be made of a plastic interlayer material(s), such as a polyvinyl butyral (PVB) film. In some embodiments, the outer glass layer 202 and the inner glass layer 204 are made of glass, polycarbonate (PC) materials, acrylic materials such as polymethyl methacrylate (PMMA), thermoplastics such as thermoplastic polyurethane (TPU), and/or glass-ceramic materials, such as soda-lime-silica glass-ceramics, aluminosilicate glass-ceramics, lithium aluminosilicate glass-ceramics, spinel glass-ceramics, and beta-quartz glass-ceramics. The bonding layer 208 can be made of the same or different materials as the inner reinforcing layers 206.

The thickness of each of the laminate layers of the laminated glass panel 106 is not meant to be particularly limited and will vary depend on the needs of a respective application (e.g., desired structural, thermal, and optical properties, etc.). In some embodiments, for example, the outer glass layer 202, the inner glass layer 204, the inner reinforcing layers 206, and the bonding layer 208 are each formed to a thickness of 1 to 100 microns, or more (e.g., layers can be several inches thick if desired).

The piezoelectric device 108 can be laminated between the laminate layers of the laminated glass panel 106 during the glass-PVB lamination process. In some embodiments, the piezoelectric device 108, the outer glass layer 202, the inner glass layer 204, the inner reinforcing layers 206 (e.g., PVB films), and the bonding layer 208 are heat-sealed under pressure to laminate the final structure (i.e., the laminated glass panel 106). In some embodiments, the piezoelectric device 108 can be made of a same or smaller thickness as the bonding layer 208. In some embodiments, the piezoelectric device 108 is placed in a cutout in the bonding layer 208 prior to the glass/PVB/glass lamination process.

In some embodiments, lamination involves heating (e.g., at temperatures greater than 100 degrees Celsius) and quenching in an autoclave under a pressure of 10 kg−f/cm² or higher, although other lamination conditions (temperatures, pressures, etc.) are within the contemplated scope of this disclosure. In some embodiments, the laminated glass panel 106 can be formed to a total post-lamination thickness of 0.1 mm to 10 mm or greater (e.g., 0.3 mm, 0.7 mm, 2 mm, an inch, several inches, etc.), depending on the application and design targets.

Turning now to the piezoelectric device 108, in some embodiments, the piezoelectric device 108 includes an actuator 210 and a displaceable element 212 electrically and/or mechanically coupled to the actuator 210. The actuator 210 can be made of any suitable piezoelectric material(s) such as, for example, lead zirconate titanate (PZT), potassium sodium niobate (KNN), bismuth sodium titanate (BNT), piezopolymers such as polyvinylidene fluoride (PVDF) and poly-L-lactic Acid (PLLA), single crystal piezoelectric materials such as lead magnesium niobate-lead titanate (PMN-PT) and lithium niobate (LiNbO₃).

These materials can be selected for their ability to induce a vertical displacement in the displaceable element 212 based on the piezoelectric effect. The piezoelectric effect is the ability of certain materials to generate an electric charge in response to mechanical stress or strain, and vice versa. In some embodiments, when an electric voltage is applied to the actuator 210, the actuator 210 undergoes a dimensional change(s) due to the piezoelectric effect. These dimensional changes can be used to generate a controlled mechanical displacement in the displaceable element 212 (represented by dashed impression lines). In some embodiments, this controlled mechanical displacement is used to vertically displace the displaceable element 212 towards and/or away from the outer glass layer 202 and the inner glass layer 204. In some embodiments, this controlled mechanical displacement is used to vertically displace the displaceable element 212 into one or both of the outer glass layer 202 and the inner glass layer 204 to initiate a crack in those respective surfaces (i.e., to damage or break the glass layers).

The displaceable element 212 can be a metal, metal alloy, and/or carbide tip that can be vertically displaced by the actuator 210, although any material sufficiently hard to damage the outer glass layer 202 and the inner glass layer 204 can be used. While not meant to be particularly limited, one or more displaceable elements 212 can alternatively, or in addition, be a plate, a rod, and/or any other form or structure that allows for vertical movement and delivery of a point force (e.g., via a tip or face) against a surface of one or both of the outer glass layer 202 and the inner glass layer 204. The displaceable element 212 can be attached to the actuator 210 mechanically and/or electrically. In this manner, when the actuator 210 undergoes dimensional changes in response to an applied voltage, the displaceable element 212 can be vertically displaced to impart a force via direct contact into the outer glass layer 202 and/or the inner glass layer 204. The magnitude of the displacement depends on the magnitude of the applied voltage delivered to the actuator 210.

In some embodiments, the vertical displacement of the actuator 210 can be precisely controlled by adjusting the voltage applied to the actuator 210 via a controller 214 (also referred to as an electrical connector). In some embodiments, the controller 214 is electrically coupled to the actuator 210 via one or more wires 216 (also referred to as signal lines). In some embodiments, a portion of the wires 216 are embedded in the laminated glass panel 106 (as shown).

In some embodiments, the controller 214 is itself electrically coupled to one or more external system(s) 218. The external system 218 can include, for example, an Electronic Control Unit (ECU) of the vehicle 100. In some embodiments, the external system 218 is a specialized computer that receives, processes, and generates electrical signals to manage and regulate the functions of one or more vehicle components (e.g., the controller 214 and/or the piezoelectric device 108).

In some embodiments, the controller 214 and/or the external system 218 is configured to predict and sense an impact of the vehicle 100. For example, the controller 214 and/or the external system 218 can be configured to predict a frontal impact, a side impact, a rear impact, etc. In some embodiments, the controller 214 and/or the external system 218 detects an upcoming impact using one or more on-board vehicle sensors (not separately shown), such as, for example, cameras, Light Detection and Ranging (LIDAR) systems, radar sensors, ultrasonic sensors, Inertial Measurement Units (IMUs) such as accelerometers and gyroscopes that measure an acceleration, orientation, and angular velocity of the vehicle 100, and/or dedicated crash sensors such as accelerometers and decelerometers.

In some embodiments, the controller 214 and/or the external system 218 is configured to send an activation voltage (using, e.g., the wires 216) to the actuator 210 responsive to predicting an upcoming impact of the vehicle 100. In some embodiments, the activation voltage causes the actuator 210 to displace the displaceable element 212 into the outer glass layer 202 and/or the inner glass layer 204 as discussed previously. In this manner, the outer glass layer 202 and/or the inner glass layer 204 can be controllably and predictably broken responsive to detecting an upcoming impact (i.e., on demand). In some embodiments, the piezoelectric devices 108 serve as crack initiators (where individual cracks are initiated at the contact point between a respective piezoelectric device and the glass).

FIG. 3 illustrates an alternative configuration of the laminated glass panel 106 shown in FIG. 2 in accordance with one or more embodiments. The laminated glass panel 106 can be manufactured in a similar manner as discussed with respect to FIG. 2, except that the laminated glass panel 106 shown in FIG. 3 includes a plurality of piezoelectric devices 108 (here, four devices) placed against a surface 302 of the inner glass layer 204. In some embodiments, one or more of the piezoelectric devices 108 are placed against a surface 304 of the outer glass layer 202 (not separately shown).

As discussed previously, in some embodiments, the controller 214 and/or the external system 218 (here, represented together) can be configured to send an activation voltage to the actuators 210 responsive to predicting an upcoming impact of the vehicle 100. In some embodiments, the controller 214 and/or the external system 218 can be configured to selectively send an activation voltage to a specific subset (one or more, but not all) of the actuators 210 responsive to predicting an upcoming impact of the vehicle 100. In this manner, the laminated glass panel 106 can be selectively weakened or otherwise damaged in a targeted location/region.

In some embodiments, the controller 214 and/or the external system 218 can be configured to detect an estimated impact region on the laminated glass panel 106. In some embodiments, the controller 214 and/or the external system 218 can be configured to activate one or more of the actuators 210 within a predetermined proximity of the estimated impact region. For example, the controller 214 and/or the external system 218 can be configured to activate the subset of the actuators 210 directly within the estimated impact region, or alternatively within a predetermined distance (e.g., 1 mm, 1 inch, 5 inches, 1 foot, etc.) of a boundary of the estimated impact region. The activated subset of the actuators 210 are represented in FIG. 2 by the stylized arrows. Notably, in some embodiments, one or more of the actuators 210 (i.e., those outside of the estimated impact region and/or the predetermined distance from that region) remain inactivated. The inactivated subset of the actuators 210 are represented in FIG. 2 by the stylized crosses.

FIG. 4 illustrates an alternative configuration of the laminated glass panel 106 shown in FIG. 2 in accordance with one or more embodiments. The laminated glass panel 106 can be manufactured in a similar manner as discussed with respect to FIG. 2, except that the laminated glass panel 106 shown in FIG. 4 includes both a plurality of piezoelectric devices 108 (here, four devices) placed against a surface 302 of the inner glass layer 204 and one or more piezoelectric devices 108 (here, two) embedded within the bonding layer 208.

As further shown in FIG. 4, the two piezoelectric devices 108 embedded within the bonding layer 208 can be situated together in an orientation facing away from one another. In this manner, activating the two piezoelectric devices 108 will cause them to press against each other, greatly increasing the force applied against the outer glass layer 202 and/or the inner glass layer 204 (as the force applied against each other must itself be redirected).

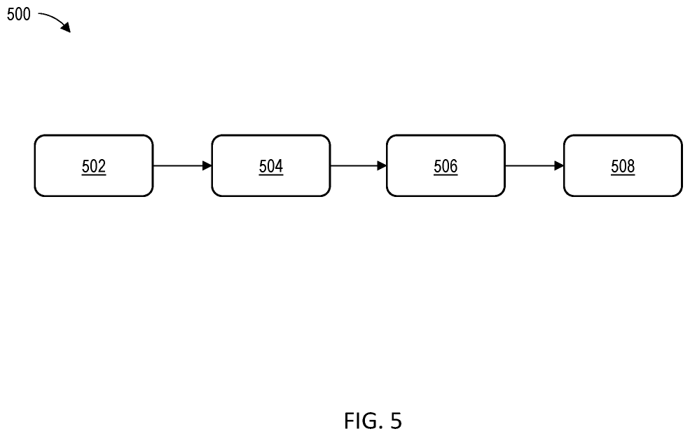

FIG. 5 illustrates a process 500 for using a piezoelectric device to break a laminated glass assembly on demand in accordance with one or more embodiments. The process 500 can be carried out using, for example, the piezoelectric devices 108 of the vehicle 100 to break the laminated glass panel 106 (refer to FIG. 1). It should be understood that, while the process 500 is largely discussed with respect to a single piezoelectric device for convenience, the underlying techniques can be applied to any number of piezoelectric devices.

The process 500 begins at step 502, where a vehicle impact is sensed or otherwise detected. The vehicle impact can be a predicted (upcoming) impact or an actual impact occurring immediately. In some embodiments, the vehicle impact is a predicted frontal vehicle impact. The impact can be sensed or predicted using, for example, an ECU of the vehicle 100.

At step 504, a signal is sent to activate the piezoelectric device. The signal can include an activation voltage applied to an actuator of the piezoelectric device. For example, a voltage can be applied to the actuator 210.

At step 506, the actuator causes a displaceable element to strike the laminated glass assembly. For example, the actuator 210 can cause a displacement of the displaceable element 212 into the outer glass layer 202 and/or the inner glass layer 204 of the laminated glass panel 106.

At step 508, a crack is formed (crack initiation begins) at the location of the strike. For example, a crack can form where the displaceable element 212 impacts the outer glass layer 202 and/or the inner glass layer 204 of the laminated glass panel 106. In this manner, the laminated glass panel 106 can be damaged prior to the actual impact.

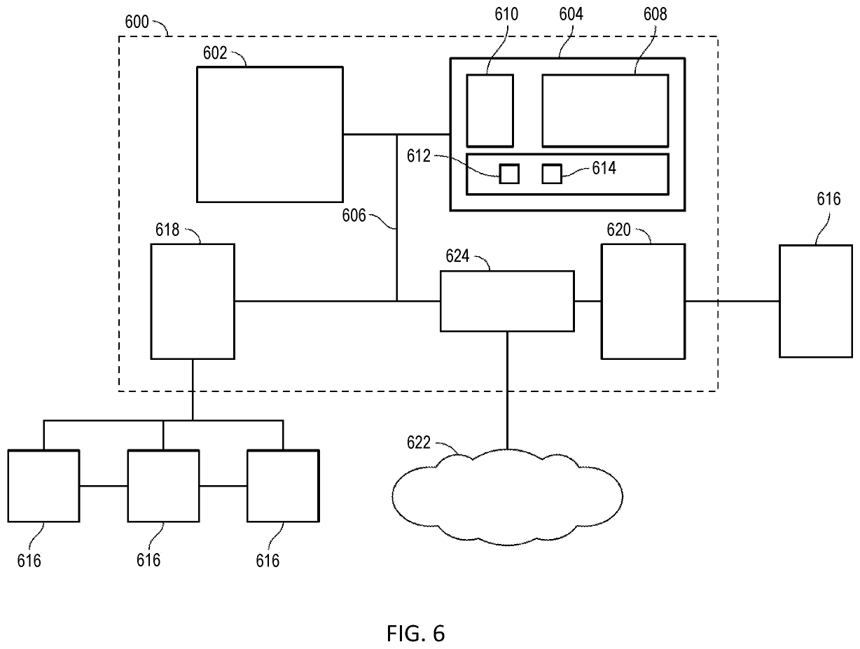

FIG. 6 illustrates aspects of an embodiment of a computer system 600 that can perform various aspects of embodiments described herein. In some embodiments, the computer system 600 can be incorporated within or in combination with a controller (e.g., controller 214) and/or an external system (e.g., external system 218) of the vehicle 100 (refer to FIGS. 1 to 4). The computer system 600 includes at least one processing device 602, which generally includes one or more processors for performing a variety of functions, such as, for example, detecting/predicting impacts and controlling activation voltages to one or more actuators of one or more piezoelectric devices. More specifically, the computer system 600 can include the logic necessary to detect and/or predict an impact to a vehicle and to direct an activation voltage to an actuator of a piezoelectric device responsive to detecting and/or predicting the impact.

Components of the computer system 600 include the processing device 602 (such as one or more processors or processing units), a system memory 604, and a bus 606 that couples various system components including the system memory 604 to the processing device 602. The system memory 604 may include a variety of computer system readable media. Such media can be any available media that is accessible by the processing device 602, and includes both volatile and non-volatile media, and removable and non-removable media.

For example, the system memory 604 includes a non-volatile memory 608 such as a hard drive, and may also include a volatile memory 610, such as random access memory (RAM) and/or cache memory. The computer system 600 can further include other removable/non-removable, volatile/non-volatile computer system storage media.

The system memory 604 can include at least one program product having a set (e.g., at least one) of program modules that are configured to carry out functions of the embodiments described herein. For example, the system memory 604 stores various program modules that generally carry out the functions and/or methodologies of embodiments described herein. A module or modules 612, 614 may be included to perform functions related to impact detection and/or control of an actuator of one or more piezoelectric devices. The computer system 600 is not so limited, as other modules may be included depending on the desired functionality of the vehicle 100. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. For example, the module(s) can be configured via software, hardware, and/or firmware to cause a signal (an activation voltage) to be applied to an actuator of one or more piezoelectric devices.

The processing device 602 can also be configured to communicate with one or more external devices 616 such as, for example, a keyboard, a pointing device, and/or any devices (e.g., a network card, a modem, additional vehicle ECUs, etc.) that enable the processing device 602 to communicate with one or more other computing devices. Communication with various devices can occur via Input/Output (I/O) interfaces 618 and 620.

The processing device 602 may also communicate with one or more networks 622 such as a local area network (LAN), a general wide area network (WAN), a bus network and/or a public network (e.g., the Internet) via a network adapter 624. In some embodiments, the network adapter 624 is or includes an optical network adaptor for communication over an optical network. It should be understood that although not shown, other hardware and/or software components may be used in conjunction with the computer system 600. Examples include, but are not limited to, microcode, device drivers, redundant processing units, external disk drive arrays, RAID systems, and data archival storage systems, etc.

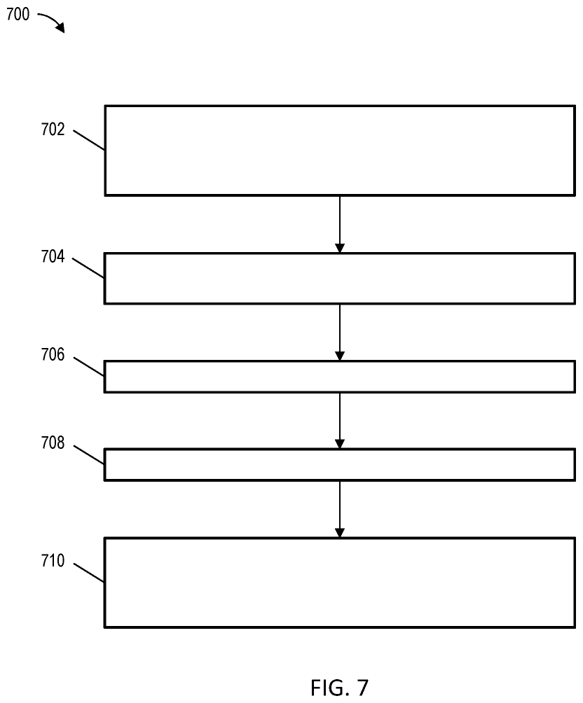

Referring now to FIG. 7, a flowchart 700 for using a piezoelectric device to break a laminated glass assembly on demand is generally shown according to an embodiment. The flowchart 700 is described in reference to FIGS. 1 to 6 and may include additional steps not depicted in FIG. 7. Although depicted in a particular order, the blocks depicted in FIG. 7 can be rearranged, subdivided, and/or combined.

At block 702, the method includes providing a piezoelectric system. The piezoelectric system includes a laminated glass panel having an outer glass layer, an inner glass layer, and a bonding layer between the outer glass layer and the inner glass layer.

At block 704, the method includes providing a piezoelectric device having an actuator and a displaceable element coupled to the actuator. The actuator includes a piezoelectric material that, responsive to receiving an activation voltage, induces a mechanical displacement in the displaceable element against at least one of the outer glass layer and the inner glass layer.

In some embodiments, the piezoelectric device is embedded within the bonding layer of the laminated glass panel. In some embodiments, the piezoelectric device is positioned against a surface of at least one of the outer glass layer and the inner glass layer of the laminated glass panel.

At block 706, the method includes a controller electrically coupled to the actuator. The controller is configured to deliver the activation voltage to the actuator.

At block 708, the method includes detecting an upcoming impact.

At block 710, the method includes, responsive to detecting the upcoming impact, causing the controller to deliver the activation voltage to the actuator, thereby displacing the displaceable element into at least one of the outer glass layer and the inner glass layer.

In some embodiments, the piezoelectric system further includes an external system electrically coupled to the controller. The external system is configured to predict the upcoming impact and, responsive to predicting the upcoming impact, direct the controller to deliver the activation voltage to the actuator. In some embodiments, the external system includes one or more on-board vehicle sensors configured to detect the upcoming impact. In some embodiments, the one or more on-board vehicle sensors include at least one of a camera, a LIDAR system, a radar sensor, an ultrasonic sensor, an IMU, an accelerometer, a decelerometer, a gyroscope, and a dedicated crash sensor.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A vehicle comprising:
a laminated glass panel comprising an outer glass layer, an inner glass layer, and a bonding layer between the outer glass layer and the inner glass layer;
a piezoelectric device comprising an actuator and a displaceable element coupled to the actuator, the actuator comprising a piezoelectric material that, responsive to receiving an activation voltage, induces a mechanical displacement in the displaceable element against at least one of the outer glass layer and the inner glass layer; and
a controller electrically coupled to the actuator, the controller configured to deliver the activation voltage to the actuator.

2. The vehicle of claim 1, wherein the piezoelectric device is embedded within the bonding layer of the laminated glass panel.

3. The vehicle of claim 1, wherein the piezoelectric device is positioned against a surface of at least one of the outer glass layer and the inner glass layer of the laminated glass panel.

4. The vehicle of claim 1, further comprising an external system electrically coupled to the controller, the external system configured to:
predict an upcoming impact of the vehicle; and
responsive to predicting the upcoming impact, direct the controller to deliver the activation voltage to the actuator.

5. The vehicle of claim 4, wherein the external system comprises one or more on-board vehicle sensors configured to detect the upcoming impact.

6. The vehicle of claim 5, wherein the one or more on-board vehicle sensors comprise at least one of a camera, a Light Detection and Ranging (LIDAR) system, a radar sensor, an ultrasonic sensor, an Inertial Measurement Unit (IMU), an accelerometer, a decelerometer, a gyroscope, and a dedicated crash sensor.

7. The vehicle of claim 1, wherein the piezoelectric material comprises at least one of lead zirconate titanate (PZT), potassium sodium niobate (KNN), bismuth sodium titanate (BNT), polyvinylidene fluoride (PVDF), poly-L-lactic Acid (PLLA), lead magnesium niobate-lead titanate (PMN-PT), and lithium niobate (LiNbO₃).

8. The vehicle of claim 1, further comprising a plurality of piezoelectric devices embedded within or positioned beside the laminated glass panel.

9. The vehicle of claim 8, wherein the controller is further configured to selectively deliver the activation voltage to a subset of the plurality of piezoelectric devices.

10. A laminated glass panel comprising:
an outer glass layer;
an inner glass layer;
a bonding layer between the outer glass layer and the inner glass layer; and
a piezoelectric device comprising an actuator and a displaceable element coupled to the actuator, the actuator comprising a piezoelectric material that, responsive to receiving an activation voltage, induces a mechanical displacement in the displaceable element against at least one of the outer glass layer and the inner glass layer.

11. The laminated glass panel of claim 10, wherein a controller is electrically coupled to the actuator, the controller configured to deliver the activation voltage to the actuator.

12. The laminated glass panel of claim 10, wherein the piezoelectric device is embedded within the bonding layer of the laminated glass panel.

13. The laminated glass panel of claim 10, wherein the piezoelectric device is positioned against a surface of at least one of the outer glass layer and the inner glass layer of the laminated glass panel.

14. The laminated glass panel of claim 10, wherein the piezoelectric material comprises at least one of lead zirconate titanate (PZT), potassium sodium niobate (KNN), bismuth sodium titanate (BNT), polyvinylidene fluoride (PVDF), poly-L-lactic Acid (PLLA), lead magnesium niobate-lead titanate (PMN-PT), and lithium niobate (LiNbO₃).

15. A method for breaking laminated glass assemblies on demand, the method comprising:
providing a piezoelectric system comprising:
a laminated glass panel comprising an outer glass layer, an inner glass layer, and a bonding layer between the outer glass layer and the inner glass layer;
a piezoelectric device comprising an actuator and a displaceable element coupled to the actuator, the actuator comprising a piezoelectric material that, responsive to receiving an activation voltage, induces a mechanical displacement in the displaceable element against at least one of the outer glass layer and the inner glass layer; and
a controller electrically coupled to the actuator, the controller configured to deliver the activation voltage to the actuator;
detecting an upcoming impact; and
responsive to detecting the upcoming impact, causing the controller to deliver the activation voltage to the actuator, thereby displacing the displaceable element into at least one of the outer glass layer and the inner glass layer.

16. The method of claim 15, wherein the piezoelectric device is embedded within the bonding layer of the laminated glass panel.

17. The method of claim 15, wherein the piezoelectric device is positioned against a surface of at least one of the outer glass layer and the inner glass layer of the laminated glass panel.

18. The method of claim 15, wherein the piezoelectric system further comprises an external system electrically coupled to the controller, the external system configured to predict the upcoming impact and, responsive to predicting the upcoming impact, direct the controller to deliver the activation voltage to the actuator.

19. The method of claim 18, wherein the external system comprises one or more on-board vehicle sensors configured to detect the upcoming impact.

20. The method of claim 19, wherein the one or more on-board vehicle sensors comprise at least one of a camera, a Light Detection and Ranging (LIDAR) system, a radar sensor, an ultrasonic sensor, an Inertial Measurement Unit (IMU), an accelerometer, a decelerometer, a gyroscope, and a dedicated crash sensor.
